(19) United States
(12) Patent Application Publication
(10) Pub. No.: US 2004/0026258 A1
(43) Pub. Date: Feb. 12, 2004

(54) Method for forming high reflective micropattern

(76) Inventors: Chang Ho No, Suwon-Shi (KR); Soon Taik Hwang, Seongnam-Shi (KR); Young Hun Byun, Daejun-Shi (KR); Byong Ki Yun, Daejun-Shi (KR); Jin Young Kim, Suwon-Shi (KR)

Correspondence Address: BIRCH STEWART KOLASCH & BIRCH, PO BOX 747, FALLS CHURCH, VA, 22040-0747, US

(21) Appl. No.: 10/606,353

(22) Filed: Jun. 26, 2003

(30) Foreign Application Priority Data
Jun. 26, 2002 (KR) 2002-35988

(51) Int. Cl. C23C 16/48

(52) U.S. Cl. 205/159; 427/304; 427/582; 427/248.1; 427/282; 205/183

(57) ABSTRACT

Disclosed is a method for forming a high reflective micropattern, comprising forming a micropattern using an organometallic compound in a photoreaction or with thermal energy; and growing crystal, using the pattern as the nucleus for growing crystal, by an electro or electroless plating process. The method forms a high reflective metal pattern rapidly and efficiently without using conventional chemical vapor deposition or physical deposition methods such as sputtering.

### BACKGROUND OF THE INVENTION

This non-provisional application claims priority under 35 U.S.C. § 119(a) to Korean Patent Application No. 2002-35988 filed Jun. 26, 2002, which is herein incorporated by reference.

1. Field of the Invention

The present invention relates to a method for forming a high reflective micropattern, and more particularly to a method for rapidly and efficiently forming a high reflective reflector pattern, which comprises forming a pattern using an organometallic complex by a photoreaction or by thermal energy, and thereby obtaining a resultant pattern through plating using the pattern as a nucleus for crystal growth.

2. Description of the Related Art

As mobile communication terminals such as cell phones, notebook computers and the like are rapidly distributed, devices for displaying power consumption and remaining battery capacity are required. Because conventional transmissive display devices require back lights for enabling a user to recognize pixels, power consumption is enormous. Accordingly reflective and transflective display devices using natural light have been highlighted in articles showing that they need less battery power and are lightweight (Japan Monthly Display, January, pp. 1-5 (2002)). As the display devices, reflective liquid crystal display devices capable of displaying images only by natural light and transflective liquid crystal display devices using back lights in dark places are currently used. FIGS. 1A and 1B are explanatory diagrams showing the operational principle of the liquid crystal display devices. However, the currently used reflective and transflective liquid crystal display devices are unsatisfactory because of their low brightness and unnatural color expressions. It is known that when Ag-based compounds are used instead of the Al-based compounds widely used in the reflective and transflective display devices, the brightness of the reflectors increases by at least 10% (Optical materials, Joseph H. Simmons, Academic Press, 2000).

However, the Ag-based compounds have a disadvantage in that they are likely to be peeled off during subsequent treatment due to poor adhesiveness to substrates. Further, research on etching steps during pattern formation using a photoresist has not been developed well.

For forming a metal pattern in reflectors of reflective display devices, a metal thin film is formed through chemical vapor deposition, plasma deposition or electroplating using an organometallic material containing Al or Ag or through a sputtering process. Then, a photoresist is applied to the metal thin film by spin-coating, and a pattern is formed thereon via photolithography. Finally, etching is processed on the metal thin film to obtain a resultant pattern.

FIG. 2 is a schematic diagram illustrating a specific method of forming a reflector pattern in accordance with the prior art. Referring to FIG. 2, a metal is formed into a metal thin film by a sputtering process, and a photoresist is applied to the metal thin film. Thereafter, the photoresist is exposed to a UV light source through a mask, and subjected to baking and development to form a pattern. The pattern is used as a resist to etch the metal and the pattern is stripped after forming the desired metal pattern.

The conventional methods require high temperatures and vacuum apparatuses, and essentially involve the steps of forming a pattern using a photoresist and etching to remove the undesired metal. In addition, because these steps further include many sub-steps, they are unfavorable in terms of manufacturing costs.

Also, because the respective pattern forming process typically consists of applying a photoresist on the surface of a substrate, irradiating the photoresist with UV, e-beam or X-ray to change the characteristics of the selected area, and chemical treatment to remove the exposed or unexposed area of a photoresist, the resolution of the patterns are deteriorated with repetition of the above steps.

Others have employed a variety of methods for forming a metal pattern that does not involve a photoresist process. For example, Japanese Patent Laid-open Publication No. 62263973 discloses a method for forming a metal pattern by irradiating an organometallic thin film with an electron beam. Also, U.S. Pat. No. 5,064,685 discloses a method for forming a metal pattern including coating a metal-organic ink on a substrate and heat decomposing the metal-organic ink with a laser. This method, however, suffers from the problems that the substrate is exposed to high temperatures, and that materials other than metals cannot be used for the deposition.

U.S. Pat. No. 5,534,312 discloses a method for making a metal pattern comprising the steps of coating an organometallic compound, synthesized by coordinating an organic compound having a photo sensitivity to a metal on a substrate, and irradiating the organometallic compound with a light without using a photoresist.

In this patent, ligands participating in coordinate bonding with the metal are selected from the group consisting of acetylacetonates, dialkyldithiocarbamates, carboxylates, pyridines, amines, diamines, arsines, diarsines, phosphines, diphosphines, arenes, alkoxy ligands, alkyl ligands and aryl ligands. To enhance the desired photochemical characteristics, including the heat-decomposition tendency of the photochemical reaction product, at least one ligand selected from the group consisting of oxalato, halogens, hydrogen, hydroxy, cyano, carbonyl, nitro, nitrate, nitrosyl (NO⁻), ethylene, acetylene, thiocyanato (NCS⁻), isothiocyanato (SCN⁻), aquo, azides, carbonate, amine and thiocarbonyl is used alone or in combination with the ligands listed above.

In accordance with the patent, after applying the organometallic compound on the substrate, followed by irradiating the substrate with a light through a patterned mask, the light reacts with the organometallic compound. By the reaction, organic ligands coordinated to the metals decompose and are separated. The remaining metals are bound to other adjacent metal atoms to form a metal pattern, or react with oxygen in the air to form a metal oxide pattern.

However, this method suffers from the problem of ligand contamination because most of the ligands are not separated by the photoreaction. Further, an additional problem is that reduction and heat treatment must be carried out at a temperature of 200° C. or more for 30 minutes to several hours under a flow of hydrogen/nitrogen mixed gas, in order to improve electrical conductivity of the metal oxide pattern. Furthermore, since the ligands used in the method have relatively large steric hindrance, large voids occur when the organometallic compound is decomposed by light irradiation. Accordingly, shrinkage in the thickness of the metal film is as high as 75-90%, which leads to the cracking and crazing of the metal film.

### SUMMARY OF THE INVENTION

Therefore, it is a feature of the present invention to provide a method for rapidly and efficiently forming a high reflective reflector pattern, which comprises forming a pattern using an organometallic complex by a photoreaction or thermal energy, and obtaining a resultant pattern through plating using the pattern as a nucleus for crystal growth.

In accordance with an aspect of the present invention, there is provided a method for forming a high reflective reflector pattern which comprises: forming an organometallic compound into a micropattern by a photoreaction or thermal energy; and growing crystal, using a pattern as a nucleus for growing crystal, wherein the crystal growth is by an electro or electroless plating process.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A and 1B are explanatory diagrams showing the operational principle of reflective and transflective liquid crystal display devices, respectively;

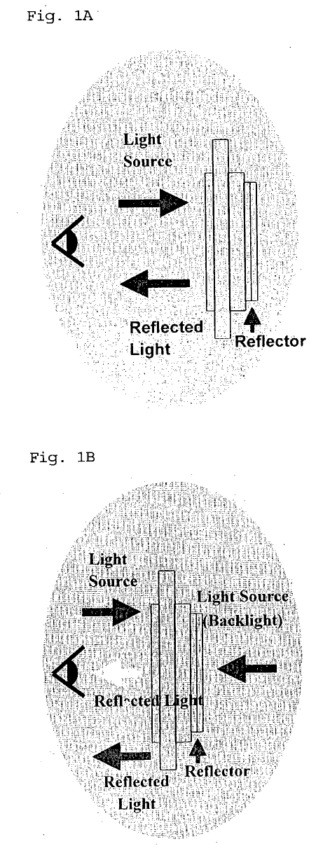

FIG. 2 is a schematic diagram illustrating the formation steps of a reflector pattern in accordance with the prior art; and

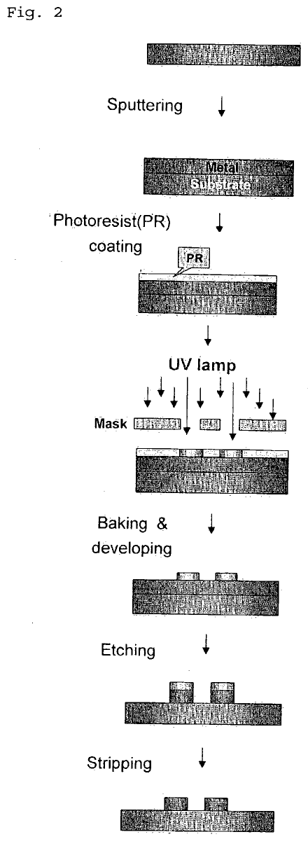

FIG. 3 is a schematic diagram illustrating the formation steps of a reflector pattern in accordance with the present invention.

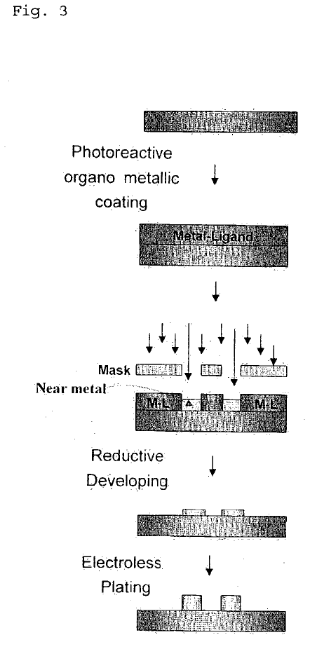

### DESCRIPTION OF THE PREFERRED EMBODIMENTS

Hereinafter, the present invention will be explained in more detail.

An organometallic compound used in a method for forming a micropattern according to the present invention is represented by the following formula 1:

MₘLₙXₚ (1)

wherein M is a transition metal, lanthanide or representative element metal; L is a ligand; X is a monovalent to trivalent anion; m is an integer from 1 to 10, and when m is 2 or more, M may be different from each other; n is an integer from 0 to 60, and when n is 2 or more, L may be different from each other; p is an integer from 0 to 60, and when p is 2 or more, X may be different from each other; L may act as a ligand bonding two metals when two or more metals are used; and n and p are not simultaneously 0.

The number of the ligands in the organometallic compound depends on the types and oxidation numbers of the metals. 0 to 6 ligands can be coordinated per metal. In addition, 0 to 6 anions can be coordinated per metal.

The metal M constituting the organometallic compound is preferably a late transition metal (IX-XII) selected from the group consisting of Co, Ni, Pd, Pt, Cu, Ag, Au, Zn and Cd, or a representative element metal such as Al.

L is a ligand coordinated to the metal, and an organic compound containing a electron donating atom such as N, P, As, O, S, Se and Te, and preferably has 20 or less carbon atoms. Specific examples of L include anionic ligands such as acetylacetonates, acetates, β-ketoiminates, β-diiminates, βketoesters, dialkyldithiocarbamates, carboxylates, oxalato, halogens, hydrogen, hydroxy, cyano, nitro, nitrate, nitrosyl (NO⁻), azides, thiocyanato (NCS⁻), isothiocyanato (SCN⁻), alkoxy ligands and a derivative thereof; and neutral ligands such as pyridines, amines, diamines, arsines, diarsines, phosphines, diphosphines, arenes, carbonyl, imidazolylidene, ethylene, acetylene, aquo, thiocarbonyl, thioether and a derivative thereof.

X is an anion, and acts to neutralize the organometallic compound. X may be coordinated or uncoordinated to the metal atoms. Specific examples of X include halogens, hydroxy, cyano (CN⁻), nitro (NO₂⁻), nitrate (NO₃⁻, nitrosyl (NO⁻), azide (N₃⁻), thiocyanate (NCS⁻), isothiocyanate (SCN⁻), tetraalkylborate (BR₄⁻, R=methyl, ethyl or phenyl group), tetrahaloborate (BX₄⁻, X=F, Br), hexafluorophosphate (PF₆⁻), triflate (CF₃SO₃⁻), tosylate (Ts⁻), sulfate (SO₄²⁻), carbonate (CO₃²⁻), etc.

Materials of a substrate used in a method for forming a metal pattern according to the present invention are not particularly limited, so far as they do not detract from the object of the present invention. For example, the substrate may be composed of an inorganic material such as silicon or glass, an organic material such as plastics, or a composite of inorganic materials and organic materials.

In the method for forming a micropattern using the organometallic compounds, a photoreaction or thermal energy can be used. Hereinafter, the method is specifically explained.

The method for forming a micropattern through a photoreaction comprises: (a) coating an organometallic compound on a substrate to form a thin film; (b) exposing the thin film to light through a mask to decompose the organometallic compound at the exposed area and to induce a difference in solubility between the exposed and unexposed areas, and developing the thin film to remove the organometallic compound of the unexposed area; and (c) reducing or oxidizing the exposed area to form a metal pattern or metal oxide pattern.

On the other hand, the method for forming a micropattern through thermal energy includes: (a) forming a pattern using an orgaometallic compound through 1) a soft type of lithography such as microcontact printing, micromolding in capillaries (MIMIC), etc., or 2) a direct printing process such as an ink jet printing; and (b) heating the pattern to decompose the organometallic compound.

In these methods, the metal pattern is rapidly and efficiently formed without undergoing exposure to light using a separate mask pattern and subsequent development.

Hereinafter, the method for forming a micropattern through a photoreaction is explained in more detail. First, an organometallic compound is dissolved in an appropriate organic solvent, and the resulting solution is coated on a substrate to form an organometallic compound thin film. As the coating method, spin coating, roll coating, dip coating, spray coating, flow coating, etc., may be used, and spin coating is preferred. In addition to the listed coating methods, screen-printing and thermal evaporation may be used. However, the coating method used in the present invention is not limited

Examples of the organic solvent used in the invention include, but are not limited to, nitrile-based solvents such as acetonitrile, propionitrile, pentanenitrile, hexanenitrile, heptanenitrile, isobutylnitrile, etc.; aliphatic hydrocarbon solvents such as hexane, heptane, octane, dodecane, etc.; aromatic hydrocarbon solvents such as anisole, mesitylene, xylene, etc.; ketone-based solvents such as methyl isobutyl ketone, 1-methyl-2-pyrrolidinone, cyclohexanone, acetone, etc.; ether-based solvents such as tetrahydrofuran, diisobutyl ether, isopropyl ether, etc.; acetate-based solvents such as ethyl acetate, butyl acetate, propylene glycol methylether acetate, etc.; alcohol-based solvents such as isopropyl alcohol, butyl alcohol, hexyl alcohol, octyl alcohol, etc.; inorganic solvents; and mixtures thereof.

The organometallic compound thin film thus formed is exposed to light through a mask to decompose the organometallic compound to cause a difference of solubility between the exposed and unexposed areas. That is, the organometallic compound at the exposed area is transformed. Separation of ligands from metal atoms through electromagnetic radiation accelerates the decomposition of the organometallic compound. Finally, the organometallic compound is transformed into a pure metal or a metal oxide, depending on the atmosphere. The photochemical reaction mechanism of the organometallic compound varies depending on the kind of metal and the ligands coordinated to the metals. However, it is generally contemplated that after bonds between the metals and the ligands are made unstable, the bonds are cleaved and finally decomposed by action of a metal to ligand charge transfer, a ligand to metal charge transfer, a d-d excitation state or intramolecular charge transfer. Light sources used for the electromagnetic radiation are preferably UV-light, but are not particularly limited.

In prior art methods, the organometallic compound is continuously exposed to light until the organometallic compound is completely decomposed and transformed to a pure metal or metal oxide. In the present invention, however, the organometallic compound is exposed to light to an extent that the organometallic compound at the exposed area is not dissolved in a solvent, thereby minimizing the exposure time and thus increasing productivity of the metal micropattern. This is one of the most important advantages of the present invention.

After exposure to light, the unexposed area can be removed by being dissolved in the same solvent used in the coating process of the organometallic compound on the substrate, or in other solvents. The exposed area remains undissolved to form a desired pattern. As a developing solvent, coating solvents listed above and inorganic solvents, such as tetramethylammonium hydroxide (TMAH) used in semiconductor manufacturing processes, can be used. Also, plural solvents can be used in turn.

Light exposure and development can be carried out under vacuum, or in an atmosphere of air, oxygen, hydrogen, nitrogen, argon or a mixed gas thereof at room temperature or at any temperature where the organometallic compound does not thermally decompose.

If desired, the composite of the pattern formed after development can be changed into a pure metal or metal oxide by a chemical reaction. Reduction is carried out to obtain a pure metal pattern, while oxidation is carried out to obtain a metal oxide pattern.

As a reducing agent, an organic or inorganic reducing agent can be used. Examples of organic agents include hydrazines; silanes; amines and derivatives thereof, and examples of inorganic agents include metal hydrides, such as NaBH₄, LiAlH₄, etc. These organic or inorganic agents may be in pure form or solution form, and they may react with the pattern through a gas-phase or liquid-phase reaction. Further, the pattern may be heated in the presence of hydrogen at high temperatures to obtain a pure metal pattern.

As an oxidizing agent, an organic or inorganic oxidizing agent can be used.

Preferably, the pattern formed by the reduction is further subjected to annealing at 100-600° C. to increase the adhesiveness of the metal pattern to the substrate. In particular, when the substrate is plastic as disclosed in prior art methods, the substrate may be thermally deformed. Accordingly, in the methods of the prior art, it was impossible to carry out any heat treatment. In contrast, according to the present invention, since a pure metal pattern is already formed prior to heat-treatment, heat treatment can be carried out at a temperature where the characteristics of the substrate are not impaired.

More specifically, a method for forming a silver (Ag) pattern is described. First, silver (Ag) salt is reacted with an organic ligand such as alkylamine to give a highly soluble organic silver compound. The silver compound is dissolved in a nitrile-based or alcohol-based solvent, and then spin-coated on a substrate. In the case that the substrate is a polymer insulator, the substrate can be pre-treated with an acid, such as chromic acid, to increase adhesiveness. When the formed film is exposed to light through a mask, most of the organic ligands at the exposed area seem to be separated due to photoreduction. This observation is confirmed using an IR spectrometer. Then, the film is subjected to development to form a pattern on the substrate. When the pattern is reduced using an organic reducing agent, reduction is completed within several ten seconds. The formed silver pattern has high purity, compared to a pattern formed by only a photoreaction. Since the silver pattern has low electrical conductivity and optical reflectivity due to low degrees of crystallinity and density, the pattern is subjected to a crystal growth process through an electro or electroless plating using the metal pattern as a nucleus to obtain more densely textured metal patterns.

An electroless plating solution usable in the electroless plating of the present invention comprises 1) a metal salt, 2) a reducing agent, 3) a complexing agent, 4) a pH-adjusting agent, 5) a pH buffer, and 6) an improver.

The respective components of the plating solution are specifically explained.

1) The metal salt acts as a source of metal ions. As the metal salt, hydrochloric acid salts, nitric acid salts, hydrocyanic acid salts, etc., can be used. Cu, Ag and Al-based metal salts are preferred for preparing a high reflective reflector, and Ag-based metal salts are more preferred.

2) The reducing agent functions to reduce the metal ions. As the reducing agent, NaBH₄, KBH₄, NaH₂PO₂, hydrazine, formalin, polysaccharide such as glucose, etc., can be used.

3) The complexing agent is added to inhibit metal hydroxide from being precipitated in an alkaline solution, and to adjust the concentration of free metal ions, thereby inhibiting the decomposition of the metal salts and controlling the plating rate. As the complexing agent, ammonia solution, acetic acid, guanyl acid, organic amines, etc., can be used.

4) The pH-adjusting agent is added to adjust pH of the plating solution. As the pH-adjusting agent, various acidic or basic compounds are used.

5) The pH buffer is added to inhibit pH change of the plating solution. As the pH buffer, various organic acids and weakly acidic inorganic compounds can be used.

6) The improver is added to improve coating characteristics and smoothing characteristics. As the improver, common surfactants and any adsorbents capable of adsorbing components inhibiting crystal growth can be used.

An electro plating solution usable in the electro plating process of the present invention comprises the same components as the electroless plating solution, except that electricity is applied to reduce the metal salts, instead of the reducing agent.

To inhibit crystal growth in the unexposed area during electro or electroless plating, unexposed areas can be subjected to passivation. Passivation is carried out by treating with a compound, which does not react with metals but reacts with the substrate. The compound for passivation inhibits crystal growth or makes the grown crystal easily removable, even though crystal growth takes place. In the case that the substrate is made of a dielectric material such as glass, a polymer insulator or the like, hexamethyldisilazane (HMDS), fluorine-substituted organic silicon compounds, etc., can be used as the compound for passivation.

The present invention will be described in more detail with reference to the following Examples. However, these examples are given for the purpose of illustration and are not to be construed as limiting the scope of the invention.

### PREPARATIVE EXAMPLE 1

### Preparation of Ag(NH₂Pr)ₙ (NO₃) Mixture (n=1, 2, 3 and 4)

3.4 g (20.0 mmol) of AgNO₃ was dissolved in 15 mL of acetonitrile (CH₃CN) in a 50 mL Schlenk flask under nitrogen atmosphere, and then 1.2 g (20.3 mmol) of propylamine was added dropwise thereto using a syringe. The solution was stirred at room temperature for about 1 hour, filtered through a 0.2 μm membrane filter, and concentrated under reduced pressure for 3-4 hours excluding light to yield the titled compound as a colorless oil. The structure of the compound was identified through ¹H-NMR.

¹H-NMR(CD₃CN, ppm): 2.68 (t, 2H, N-CH₂), 1.49 (m, 2H, CH₂CH₃), 0.90 (t, 3H, CH₂CH₃)

<Wire Formation and Electroless Plating>

### EXAMPLE 1

The compound prepared in Preparative Example 1 was dissolved in acetonitrile, and spin-coated on a glass substrate. The resulting film was exposed to a broadband UV light source (Oriel, 200W) through a mask to form a pattern, followed by developing with acetonitrile. The developed pattern was subjected to reduction by dipping it in 0.1 mol % hydrazine solution in alcohol for 30 seconds. The obtained metallic wires had high visible light transmittance and electric resistance.

The metallic wires were dipped in an electroless plating solution, which is obtained by mixing a silver solution and a reducing solution having the composition shown in Table 1, respectively, at a ratio of 1:1 (v/v), and crystals of the metallic wires were grown. Finally, a high reflective reflector pattern having a 10% improved reflectivity over an Al reflector was obtained.

TABLE 1

| Silver solution | Reducing solution |
|---|---|
| 3.5 g of silver nitrate | 45 g of glucose |
| aqueous ammonia | 4 g of tartaric acid |
| (in an amount sufficient to dissolve | 11 of H2O |
| 100 ml of ethanol precipitate) | |
| 60 ml of distilled water | |
| 2.5 g of NaOH/60 ml of H₂O | |

### EXAMPLE 2

Cis-dichlorobis(triphenyl phosphine) platinum(II) was coated on a surface of an LCD glass substrate by thermal evaporation. The coated film was exposed to UV light through a mask to form a pattern, and developed with acetone. The developed pattern was subjected to reduction by dipping it in a 0.1 mol % hydrazine solution in alcohol for 30 seconds. The obtained metallic wires had high visible light transmittance and electric resistance. Electroless plating was carried out in the same manner as in Example 1 to obtain a high reflective reflector having a 10% improved reflectivity over an Al reflector.

### EXAMPLE 3

Palladium(II) acetate was dissolved in isopropanol to a concentration of 5 wt %. The solution was injected into a poly(dimethyl siloxane) (PDMS) substrate on which a micropattern is formed in capillary form. A pattern was formed through microcontact-printing. After formation of the pattern, the pattern was heated to 150° C. to volatilize the coordinated organic compound. The obtained pattern was subjected to reduction by dipping it in 0.1 mol % hydrazine in alcohol for 30 seconds. The obtained metallic wires had high visible light transmittance and electric resistance. Electroless plating was carried out in the same manner as in Example 1 to obtain a high reflective reflector having a 10% improved reflectivity over an Al reflector.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming a high reflective reflector pattern comprising:
forming a micropattern using organometallic compound through a photoreaction or thermal energy; and
growing crystal, using the pattern as a nucleus for growing crystal, by an electro or electroless plating process.

2. The method according to claim 1, wherein the micropattern is formed through the following steps:
(a) coating the organometallic compound on a substrate to form a thin film;
(b) exposing the thin film to light through a mask to decompose the organometallic compound at exposed area and to induce a difference in solubility between the exposed and unexposed areas and developing the thin film to remove the organometallic compound of the unexposed area; and
(c) reducing or oxidizing the exposed area to form a metal pattern or metal oxide pattern.

3. The method according to claim 1, wherein the micropattern is formed through the following steps:
(a) forming a pattern using the organometallic compound through soft lithography or ink jet printing; and
(b) heating the pattern to decompose the organometallic compound.

4. The method according to claim 3, wherein the soft lithography is microcontact printing or micromolding in capillaries (MIMIC).

5. The method according to claim 1, wherein the organometallic compound is represented by the following formula 1:
MₘLₙXₚ (1)
wherein M is a transition metal, lanthanide or representative element metal; L is a ligand; X is a monovalent to trivalent anion; m is an integer from 1 to 10, and when m is 2 or more, M may be different from each other; n is an integer from 0 to 60, and when n is 2 or more, L may be different from each other; p is an integer from 0 to 60, and when p is 2 or more, X may be different from each other; L may act as a ligand bonding two metals when two or more metals are used; and n and p are not simultaneously 0.

6. The method according to claim 5, wherein M is a late transition metal (IX-XII) selected from the group consisting of Co, Ni, Pd, Pt, Cu, Ag, Au, Zn and Cd, or a representative element metal.

7. The method according to claim 5, wherein L is a ligand selected from the group consisting of acetylacetonates, acetates, β-ketoiminates, β-diiminates, β-ketoesters, dialkyldithiocarbamates, carboxylates, oxalato, halogens, hydrogen, hydroxy, cyano, nitro, nitrate, nitrosyl (NO⁻), azides, thiocyanato (NCS⁻), isothiocyanato (SCN⁻), alkoxy ligands, pyridines, amines, diamines, arsines, diarsines, phosphines, diphosphines, arenes, carbonyl, imidazolylidene, ethylene, acetylene, aquo, thiocarbonyl, thioether and derivatives thereof.

8. The method according to claim 5, wherein X is an anion selected from the group consisting of halogens, hydroxy, cyano (CN⁻), nitro (NO₂⁻), nitrate (NO₃⁻), nitrosyl (NO⁻), azide (N₃⁻), thiocyanate (NCS⁻), isothiocyanate (SCN⁻), tetraalkylborate (BR₄⁻, R=methyl, ethyl or phenyl group), tetrahaloborate (BX₄⁻, X=F, Br), hexafluorophosphate (PF₆⁻), triflate (CF₃SO₃⁻), tosylate (Ts⁻) sulfate (SO₄²⁻), and carbonate (CO₃²⁻).

9. The method according to claim 6, wherein the organometallic compound is silver compound.

10. A high reflective reflector pattern that is prepared by one of methods according to claims 1 to 9.

11. A reflective or transflective liquid crystal display device containing the high reflective reflector pattern according to 10.
